(19) United States
(12) Patent Application Publication
(10) Pub. No.: US 2004/0238878 A1
(43) Pub. Date: Dec. 2, 2004

(54) Manufacturing method of a semiconductor integrated circuit device

(75) Inventors: Hidenori Sato, Ome (JP); Tsutomu Okazaki, Hitachinaka (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 10/854,315

(22) Filed: May 27, 2004

(30) Foreign Application Priority Data
May 30, 2003 (JP) 2003-155297

(51) Int. Cl. H01L 29/76

(52) U.S. Cl. 257/315

(57) ABSTRACT

A technique capable of improving the reliability, more particularly, the data retention characteristics in a semiconductor integrated circuit device having a non-volatile memory using a nitride film as a charge storage layer is provided. A control gate electrode of selecting nMIS is formed on a first region of a substrate via a gate insulator, and a charge storage layer of the memory nMIS is formed on a second region via an insulator so that the hydrogen concentration of the charge storage layer is 10²⁰ cm⁻³ or less. After forming an insulator, a memory gate electrode of the memory nMIS is formed on the second region via the insulators and the charge storage layer, and an impurity is implanted into the region adjacent to the selecting nMIS and the memory nMIS to form a semiconductor region constituting a drain region and a source region of the memory cell.

### CROSS-REFERENCE TO RELATED APPLICATION

The present application claims priority from Japanese Patent Application JP 2003-155297 filed on May 30, 2003, the content of which is hereby incorporated by reference into this application.

### TECHNICAL FIELD OF THE INVENTION

The present invention relates to a semiconductor integrated circuit device and a technique for manufacturing the semiconductor integrated circuit device. More particularly, the present invention relates to a technique effectively applied to a semiconductor integrated circuit device having a MONOS (Metal Oxide Nitride Oxide Semiconductor) structure in which a nitride film is used as a charge storage layer.

### BACKGROUND OF THE INVENTION

Since electrically rewritable non-volatile memories such as the EEPROM (Electrically Erasable Programmable Read Only Memory) and the flash memory can rewrite their programs on board, the reduction of the development time and the improvement of the development efficiency can be achieved. In addition, the electrically rewritable non-volatile memories are suitable in various applications, for example, the high-mix low-volume production, the tuning for individual demands, the program update after the shipment, and the like. Especially, in recent years, the needs for the microcomputer incorporating the MPU (Micro Processing Unit) and the EEPROM (or flash memory) have been increased.

The EEPROM having the floating electrode made of polysilicon is mainly used as the electrically rewritable non-volatile memory. However, in the EEPROM of this structure, if the oxide film surrounding the floating gate electrode has even only one defect, the charge stored in the storage node is all emitted due to the abnormal leakage because the charge storage layer is a conductor. Particularly, it is believed that the problem becomes more and more serious when the micro-fabrication and the integration of the semiconductor integrated circuit device are advanced.

In such a circumstance, the MONOS structure having a nitride film used as the charge storage layer has been attracting the attention. In this case, since the charge contributing to the data storage is stored in the discrete trap of the nitride film which is an insulator, all of the charge in the charge storage layer is not emitted even when the oxide film surrounding the storage node has the defect therein. Therefore, it is possible to improve the data retention reliability.

As a structure of the MONOS memory cell, the memory cell of the single-transistor structure is suggested. Since the memory cell of this structure is easily influenced by the disturbance in comparison to the EEPROM cell structure, the split gate type memory cell of the two-transistor structure provided with a control gate electrode is also suggested. Depending on the difference in the process of forming one gate electrode on the other gate electrode, there are some types of the split gate type memory cell, that is, the one type that the control gate electrode is formed on the other electrode, the one type that the memory gate electrode is formed on the other electrode, and the one type that the memory gate electrode is formed on the other electrode by using the sidewall method.

Note that the following technique is disclosed in, for example, Japanese Patent Laid-Open No. 2002-217317. That is, in the process of forming the dielectrics constituting the charge storage film on a bottom dielectric film, at least one dielectric contacted to the boundary with the bottom dielectric film is formed by the ALD (Atomic Layer Deposition). By doing so, the lattice matching to the underlying surface when forming the charge storage film is improved.

In addition, the following structure is also described in, for example, Japanese Patent Laid-Open No. 2002-289708. That is, a plurality of dielectric films include the nitride film and the oxide film on the nitride film, the charge trap distribution in the film thickness direction in the laminated film comprised of the nitride film and the oxide film is located in the region centered by a structure transition layer formed between the nitride film and the oxide film, and a hydrogen-free film is used to form the nitride film. In this structure, the interface trap near the structure transition layer more contributes to the charge storage than ever.

### SUMMARY OF THE INVENTION

As described in the following embodiments, the inventors of the present invention has found out it difficult that the conventional methods described above would achieve the improvement of the reliability of the semiconductor integrated circuit device with the non-volatile memory using a nitride film as a charge storage layer.

An object of the present invention is to provide a technique capable of improving the reliability of the semiconductor integrated circuit device with the non-volatile memory using a nitride film as a charge storage layer, more particularly, the data retention characteristics.

The above and other objects and novel characteristics of the present invention will be apparent from the description and the accompanying drawings of this specification.

The typical ones of the inventions disclosed in this application will be briefly described as follows.

The present invention provides a manufacturing method of a semiconductor integrated circuit device in which a non-volatile memory cell including first and second field effect transistors arranged adjacently is formed on a semiconductor substrate. The manufacturing method of a semiconductor integrated circuit device includes the steps of: forming a first gate electrode of the first field effect transistor on a first region via a first insulator; forming a charge storage layer of the second field effect transistor so as to have the hydrogen concentration of 10²⁰ cm⁻³ or less over a second region via a second insulator; forming a second gate electrode of the second field effect transistor above the second region via the second insulator and the charge storage layer; and implanting an impurity into a region adjacent to the first and second field effect transistors, thereby forming an impurity region of a first conductivity type.

In addition, the present invention provides also a manufacturing method of a semiconductor integrated circuit device in which a non-volatile memory cell including a third field effect transistor having a third gate electrode arranged between adjacent bit lines is formed on a semiconductor substrate. The manufacturing method of a semiconductor integrated circuit device includes the steps of: forming a charge storage layer so as to have the hydrogen concentration of 10²⁰ cm⁻³ or less between the adjacent bit lines over a main surface of a semiconductor substrate via a second insulator; forming a third gate electrode between the adjacent bit lines above the main surface of the semiconductor substrate via the second insulator and the charge storage layer; and implanting an impurity into the semiconductor substrate adjacent to the third gate electrode, thereby forming the bit lines.

### BRIEF DESCRIPTIONS OF THE DRAWINGS

FIG. 1 is a circuit diagram of a memory cell of a semiconductor integrated circuit device according to the first embodiment of the present invention;

FIG. 2 is a plan view showing the principal part of the memory cell according to the first embodiment of the present invention;

FIG. 3A is a sectional view showing the principal part of the device basic structure of the memory cell taken along the line A-A′ in FIG. 2 according to the first embodiment of the present invention;

FIG. 3B is a sectional view showing the principal part of the device basic structure of the memory cell taken along the line B-B′ in FIG. 2 according to the first embodiment of the present invention;

FIG. 3C is a sectional view showing the principal part of the device basic structure of the memory cell taken along the line C-C′ in FIG. 2 according to the first embodiment of the present invention;

FIG. 4 is a graph showing the amount of residual hydrogen in the nitride films formed by the CVD and the ALD;

FIG. 5 is a graph showing the data retention characteristics of the memory cells each using the nitride film formed by the CVD or the ALD;

FIG. 6A is a sectional view showing the principal part of the semiconductor substrate in the manufacturing process of the semiconductor integrated circuit device according to the first embodiment of the present invention;

FIG. 6B is a sectional view showing the principal part of the semiconductor substrate in the manufacturing process of the semiconductor integrated circuit device according to the first embodiment of the present invention;

FIG. 6C is a sectional view showing the principal part of the semiconductor substrate in the manufacturing process of the semiconductor integrated circuit device according to the first embodiment of the present invention;

FIG. 7A is a sectional view showing the principal part of the semiconductor substrate in the manufacturing process of the semiconductor integrated circuit device subsequent to FIG. 6A;

FIG. 7B is a sectional view showing the principal part of the semiconductor substrate in the manufacturing process of the semiconductor integrated circuit device subsequent to FIG. 6B;

FIG. 7C is a sectional view showing the principal part of the semiconductor substrate in the manufacturing process of the semiconductor integrated circuit device subsequent to FIG. 6C;

FIG. 8A is a sectional view showing the principal part of the semiconductor substrate in the manufacturing process of the semiconductor integrated circuit device subsequent to FIG. 7A;

FIG. 8B is a sectional view showing the principal part of the semiconductor substrate in the manufacturing process of the semiconductor integrated circuit device subsequent to FIG. 7B;

FIG. 8C is a sectional view showing the principal part of the semiconductor substrate in the manufacturing process of the semiconductor integrated circuit device subsequent to FIG. 7C;

FIG. 9A is a sectional view showing the principal part of the semiconductor substrate in the manufacturing process of the semiconductor integrated circuit device subsequent to FIG. 8A;

FIG. 9B is a sectional view showing the principal part of the semiconductor substrate in the manufacturing process of the semiconductor integrated circuit device subsequent to FIG. 8B;

FIG. 9C is a sectional view showing the principal part of the semiconductor substrate in the manufacturing process of the semiconductor integrated circuit device subsequent to FIG. 8C;

FIG. 10 is a schematic diagram for explaining the step of forming the nitride film by the ALD;

FIG. 11A is a sectional view showing the principal part of the semiconductor substrate in the manufacturing process of the semiconductor integrated circuit device subsequent to FIG. 9A;

FIG. 11B is a sectional view showing the principal part of the semiconductor substrate in the manufacturing process of the semiconductor integrated circuit device subsequent to FIG. 9B;

FIG. 11C is a sectional view showing the principal part of the semiconductor substrate in the manufacturing process of the semiconductor integrated circuit device subsequent to FIG. 9C;

FIG. 12A is a sectional view showing the principal part of the semiconductor substrate in the manufacturing process of the semiconductor integrated circuit device subsequent to FIG. 11A;

FIG. 12B is a sectional view showing the principal part of the semiconductor substrate in the manufacturing process of the semiconductor integrated circuit device subsequent to FIG. 11B;

FIG. 12C is a sectional view showing the principal part of the semiconductor substrate in the manufacturing process of the semiconductor integrated circuit device subsequent to FIG. lc;

FIG. 13A is a sectional view showing the principal part of the semiconductor substrate in the manufacturing process of the semiconductor integrated circuit device subsequent to FIG. 12A;

FIG. 13B is a sectional view showing the principal part of the semiconductor substrate in the manufacturing process of the semiconductor integrated circuit device subsequent to FIG. 12B;

FIG. 13C is a sectional view showing the principal part of the semiconductor substrate in the manufacturing process of the semiconductor integrated circuit device subsequent to FIG. 12C;

FIG. 14A is a sectional view showing the principal part of the semiconductor substrate in the manufacturing process of the semiconductor integrated circuit device subsequent to FIG. 13A;

FIG. 14B is a sectional view showing the principal part of the semiconductor substrate in the manufacturing process of the semiconductor integrated circuit device subsequent to FIG. 13B;

FIG. 14C is a sectional view showing the principal part of the semiconductor substrate in the manufacturing process of the semiconductor integrated circuit device subsequent to FIG. 13C;

FIG. 15A is a sectional view showing the principal part of the semiconductor substrate in the manufacturing process of the semiconductor integrated circuit device subsequent to FIG. 14A;

FIG. 15B is a sectional view showing the principal part of the semiconductor substrate in the manufacturing process of the semiconductor integrated circuit device subsequent to FIG. 14B;

FIG. 15C is a sectional view showing the principal part of the semiconductor substrate in the manufacturing process of the semiconductor integrated circuit device subsequent to FIG. 14C;

FIG. 16 is a sectional view showing the principal part of the device basic structure of the memory cell according to the second embodiment of the present invention;

FIG. 17 is a sectional view showing the principal part of the semiconductor substrate in the manufacturing process of the semiconductor integrated circuit device according to the second embodiment of the present invention;

FIG. 18 is a sectional view showing the principal part of the semiconductor substrate in the manufacturing process of the semiconductor integrated circuit device subsequent to FIG. 17;

FIG. 19 is a sectional view showing the principal part of the semiconductor substrate in the manufacturing process of the semiconductor integrated circuit device subsequent to FIG. 18;

FIG. 20 is a sectional view showing the principal part of the semiconductor substrate in the manufacturing process of the semiconductor integrated circuit device subsequent to FIG. 19;

FIG. 21 is a plan view showing the principal part of the memory cell according to the third embodiment of the present invention;

FIG. 22 is a sectional view showing an example of the device basic structure of the memory cell taken along the line D-D′ in FIG. 21 according to the third embodiment of the present invention;

FIG. 23 is a sectional view showing the principal part of the semiconductor substrate in the manufacturing process of the semiconductor integrated circuit device subsequent to FIG. 22;

FIG. 24 is a sectional view showing the principal part of the semiconductor substrate in the manufacturing process of the semiconductor integrated circuit device subsequent to FIG. 23;

FIG. 25 is a sectional view showing the principal part of the semiconductor substrate in the manufacturing process of the semiconductor integrated circuit device subsequent to FIG. 24;

FIG. 26 is a sectional view showing the principal part of the semiconductor substrate in the manufacturing process of the semiconductor integrated circuit device subsequent to FIG. 25;

FIG. 27 is a sectional view showing the principal part of the semiconductor substrate in the manufacturing process of the semiconductor integrated circuit device subsequent to FIG. 26;

FIG. 28 is a plan view showing the principal part of the memory cell according to the fourth embodiment of the present invention;

FIG. 29A is a sectional view showing the principal part of the device basic structure of the memory cell taken along the line E-E′ in FIG. 28 according to the fourth embodiment of the present invention;

FIG. 29B is a sectional view showing the principal part of the device basic structure of the memory cell taken along the line F-F′ in FIG. 28 according to the fourth embodiment of the present invention;

FIG. 30A is a sectional view showing the principal part of the semiconductor substrate in the manufacturing process of the semiconductor integrated circuit device according to the fourth embodiment of the present invention;

FIG. 30B is a sectional view showing the principal part of the semiconductor substrate in the manufacturing process of the semiconductor integrated circuit device according to the fourth embodiment of the present invention;

FIG. 31A is a sectional view showing the principal part of the semiconductor substrate in the manufacturing process of the semiconductor integrated circuit device subsequent to FIG. 30A;

FIG. 31B is a sectional view showing the principal part of the semiconductor substrate in the manufacturing process of the semiconductor integrated circuit device subsequent to FIG. 30B;

FIG. 32A is a sectional view showing the principal part of the semiconductor substrate in the manufacturing process of the semiconductor integrated circuit device subsequent to FIG. 31A; and

FIG. 32B is a sectional view showing the principal part of the semiconductor substrate in the manufacturing process of the semiconductor integrated circuit device subsequent to FIG. 31B; and

FIG. 33A is a sectional view showing the principal part of the semiconductor substrate in the manufacturing process of the semiconductor integrated circuit device subsequent to FIG. 32A.

FIG. 33B is a sectional view showing the principal part of the semiconductor substrate in the manufacturing process of the semiconductor integrated circuit device subsequent to FIG. 32B.

### DESCRIPTION OF THE PREFERRED EMBODIMENTS

Before the detail description of the invention in this application, the meanings of the terms used in the embodiments will be explained as follows.

The silicon nitride includes not only Si₃N₄ but also the other insulator having a similar composition to the nitride of silicon.

Hereinafter, the embodiments of the present invention will be described in detail with reference to the accompanying drawings. In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of an element (including number of pieces, values, amount, range, and the like), the number of the element is not limited to a specific number unless otherwise stated or except the case where the number is apparently limited to a specific number in principle. The number larger or smaller than the specified number is also applicable. Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. This condition is also applicable to the numerical value and the range described above. Also, components having the same function are denoted by the same reference symbols throughout the drawings for describing the embodiments, and the repetitive description thereof is omitted. In addition, the description of the same or similar portions is not repeated in principle unless particularly required in the following embodiments. Also, in the drawings used in the embodiments, hatching is used in some cases even in a plan view so as to make the drawings easy to see. Also, in the following embodiments, the MISFET (Metal Insulator Semiconductor Field Effect Transistor) is abbreviated to MIS, and the n channel MISFET is abbreviated to nMIS. Note that the MOSFET (Metal Oxide Field Effect Transistor) is the field effect transistor in which a silicon oxide film (SiO₂ and the like) forms its gate insulator and is included in the subordinate concept of the above-mentioned MIS. Also, the MONOS memory cell described in the embodiments is obviously included in the subordinate concept of the MIS.

Incidentally, the MONOS memory cell usually adopts the so-called localized storage system in which the data is written by storing the electrons in a part of the nitride film. However, in this localized storage system, the problem that the data retention characteristics become unstable because the electrons are diffused in the lateral direction in the nitride film and the written electrons are emitted in the longitudinal direction (film-thickness direction) through the upper and lower oxide films. More specifically, the threshold voltage becomes unstable after the long time data retention, the data between the adjacent memory cells is varied, and the threshold voltage is varied depending on the data writing and the data erasing.

The examination by the inventor of the present invention shows that the variation of the data retention characteristics relates to the hydrogen concentration in the nitride film. For example, the dispersion of the electrons in the lateral direction in the nitride film is caused by the electron conduction via the shallow trap level by the residual hydrogen in the nitride film. More specifically, when hydrogen is introduced to the nitride film, the Si—H bond density in the nitride film is increased. However, when hydrogen is emitted from the Si-H bond, the silicon dangling bond is created and the shallow trap level is generated. Therefore, the hopping conduction of electrons easily occurs. For example, the data variation between the adjacent memory cells each having the memory gate electrode of the same layer is caused by the conduction of the electrons in the lateral direction in the nitride film and the resulting change in the number of electrons stored in the nitride film. Therefore, it is necessary to reduce the hydrogen concentration in the entire nitride film which traps the electrons.

In addition, the nitride film is sandwiched between the oxide films and the lower oxide film is formed in order to prevent the easy emission of the electrons stored in the nitride film to the substrate side and the easy injection of the unnecessary charge into the nitride film from the substrate side. However, in the case where the holes come into the nitride film, the holes cut the Si—H bonds in the nitride film and the hydrogen ions with high energy are generated. Furthermore, when the hydrogen ions cut the Si—O bonds in the lower oxide film, the defects are formed in the oxide film. Therefore, when the hydrogen concentration in the nitride film is high and the S—H bond density is increased, the defects in the lower oxide are increased and extended in the longitudinal direction to form the leakage path, and as a result, the leakage current is increased.

However, since the nitride film is usually formed by the thermal CVD (Chemical Vapor Deposition), the hydrogen concentration of the nitride film is high about 10²¹ cm⁻³, and also, it is difficult to reduce and control the hydrogen concentration in the nitride film in the CVD.

The invention of this application is made for the purpose of solving the above-mentioned problems and the detail description thereof will be shown below.

### First Embodiment

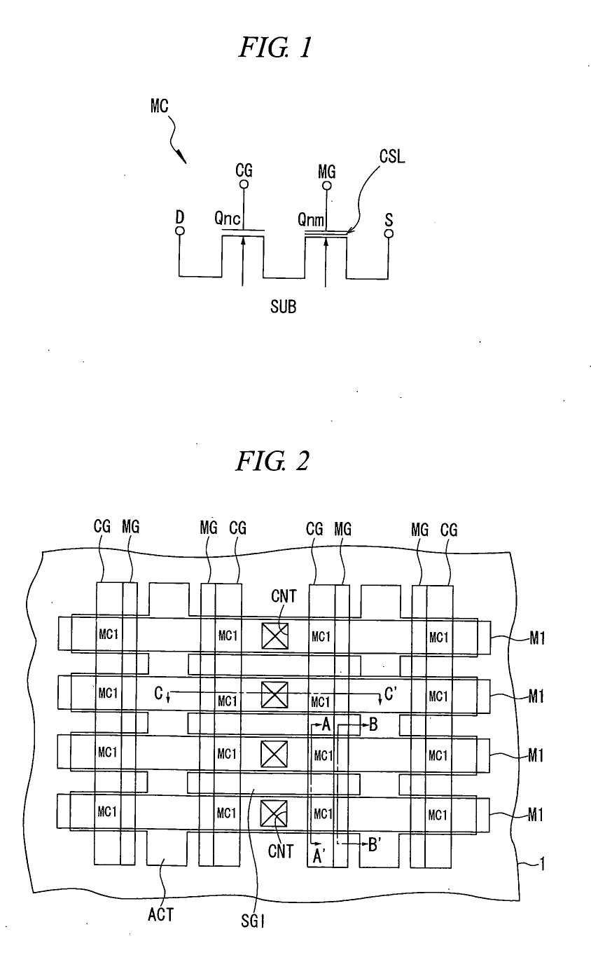

FIG. 1 is a circuit diagram showing the MONOS memory cell.

A memory cell MC has two transistors such as an n MISFET for selecting a memory cell (first field effect transistor: simply referred to as a selecting nMIS hereinafter) Qnc and an n MISFET for a memory (second field effect transistor: simply referred to as a memory n MIS hereinafter) Qnm between a drain electrode D and a source electrode S. The selecting nMIS Qnc has a control gate electrode CG, and the memory nMIS Qnm has a memory gate electrode MG and a charge storage layer CSL.

In the data reading operation, the voltage of about 1.0 V is applied to the drain electrode D of the selected memory cell MC, the voltage of about 1.5 V is applied to the control gate electrode CG, and the voltage of 0 V is applied to the source electrode S and the memory gate electrode MG of the selected memory cell MC and the substrate SUB. By doing so, the selecting nMIS Qnc of the memory cell MC is turned on. At this time, the threshold voltage of the memory nMIS Qnm is changed depending on the presence of the electrons in the charge storage layer CSL of the memory nMIS Qnm, which allows the current to pass or not to pass between the drain electrode D and the source electrode S. In this manner, the data is read.

Also, in the data erasing operation, the voltage of 0 V is applied to the drain electrode D and the source electrode S of the selected memory cell MC and the substrate SUB, the voltage of about 1.5 V is applied to the control gate CG, and the voltage of about −14.0 V is applied to the memory gate electrode MG. By doing so, holes (hot hole) generated in the channel of the memory cell MC are injected to the charge storage layer CSL, and the holes are coupled to the electrons stored in the charge storage layer CSL. In this manner, the data is erased.

Also, in the data writing operation, the voltage of 0 V is applied to the drain electrode D of the selected memory cell MC and the substrate SUB, the voltage of about 1.5 V is applied to the control gate electrode CG, the voltage of about 12.0 V is applied to the memory gate electrode MG, and the voltage of about 6 V is applied to the source electrode S of the selected memory cell MC. By doing so, the electrons (hot electron) generated in the channel of the memory cell MC are injected to the charge storage layer CSL. In this manner, the data is written.

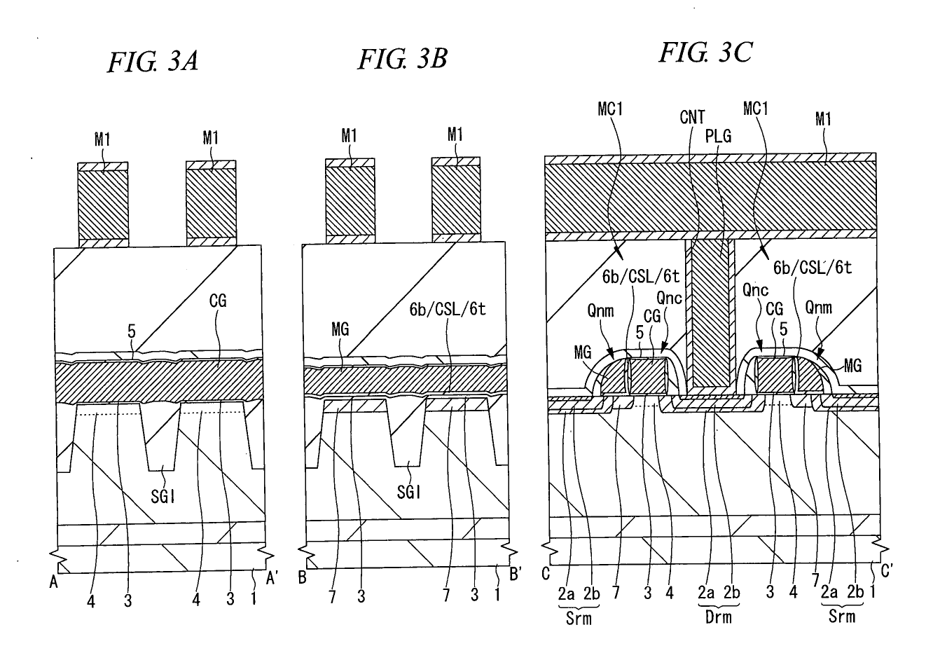

Next, an example of the memory cell structure according to the first embodiment will be described with reference to FIGS. 2 and 3. FIG. 2 is a plan view showing the principal part of the memory cell, FIG. 3A is a sectional view of the memory cell taken along the extending direction of the control gate electrode (line A-A′ in FIG. 2), FIG. 3B is a sectional view of the memory cell taken along the extending direction of the memory gate electrode (line B-B′ in FIG. 2), and FIG. 3C is a sectional view of the memory cell obtained by cutting the channel along the direction orthogonal to the memory gate electrode (line C-C′ in FIG. 2). The memory cell MC1 in which the memory gate electrode is formed on the top and the sidewall of the control gate is shown here.

A semiconductor substrate (simply referred to as a substrate hereinafter) 1 is made of, for example, p-type single crystal silicon, and the selecting nMIS Qnc and the memory nMIS Qnm of the memory cell MC1 are arranged in the active region ACT on the main surface (device forming surface) of the substrate 1. A drain region Drm and a source region Srm of the memory cell MC1 have, for example, an n⁻-type semiconductor region 2a and an n⁺-type semiconductor region 2b with higher impurity concentration than that of the semiconductor region 2a (LDD (Lightly Doped Drain) structure). The n⁻-type semiconductor region 2a is arranged on the channel region side of the memory cell MC1, and the n⁺-type semiconductor region 2b is arranged at the position away from the channel region of the memory cell MC1 by the length of the n⁻-type semiconductor region 2a.

The control gate electrode CG of the selecting nMIS Qnc and the memory gate electrode MG of the memory nMIS Qmn are extended along with each other between the drain region Drm and the source region Srm on the main surface of the substrate 1, and a plurality of memory cells MC1 are arranged along the extending direction of the gate electrode via the device isolation SGI formed on the substrate 1. The control gate electrode CG and the memory gate electrode MG are made of, for example, low-resistance n-type polysilicon. The gate length of the control gate electrode CG is, for example, about 0.20 μm and the gate length of the memory gate electrode MG is, for example, about 0.12 μm.

A gate insulator (first insulator) 3 made of-thin silicon oxide with a thickness of about 2 to 3 nm is formed between the control gate electrode CG and the main surface of the substrate 1. Therefore, the control gate electrode CG is arranged on the substrate 1 via the device isolation SGI and the gate insulator 3. A p-type semiconductor region 4 is formed in the main surface of the substrate 1 below the gate insulator 3. This semiconductor region 4 is the semiconductor region for forming the channel of the selecting nMIS Qnc, and the threshold voltage of the selecting nMIS Qnc is set to a predetermined value by this semiconductor region 4. The semiconductor region 4 has a function to increase the threshold voltage of the selecting nMIS Qnc. For example, boron (B) is introduced to the semiconductor region 4.

Meanwhile, the memory gate electrode MG is provided on the sidewall of the control gate electrode CG, and the control gate electrode CG and the memory gate electrode MG is isolated from each other by the insulator 5, the insulators 6b and 6t, and the charge storage layer CSL formed on the surface of the control gate electrode CG. In addition, the memory gate electrode MG is arranged on the device isolation SGI and the substrate 1 via the insulators 6b and 6t and the charge storage layer CSL.

The charge storage layer CSL is sandwiched between its upper and lower insulators 6b and 6t and is made of, for example, silicon nitride. Also, the thickness of the charge storage layer CSL is, for example, 50 nm or less. The insulators 6b and 6t are made of, for example, silicon oxide. The thickness of the insulator 6b is, for example, about 4 to 5 nm and the thickness of the insulator 6t is, for example, about 6 nm. It is also possible to use silicon nitride (SiON) to form the insulator 6t. Also, the insulators 6b and 6t can be formed as silicon oxide films containing nitrogen.

Also, the charge storage layer CSL is formed by the ALD (Atomic Layer Deposition) because the hydrogen concentration of the silicon oxide film formed by the ALD is lower than that formed by the CVD, and the hydrogen concentration can be reduced to 10²⁰ cm⁻³ or less.

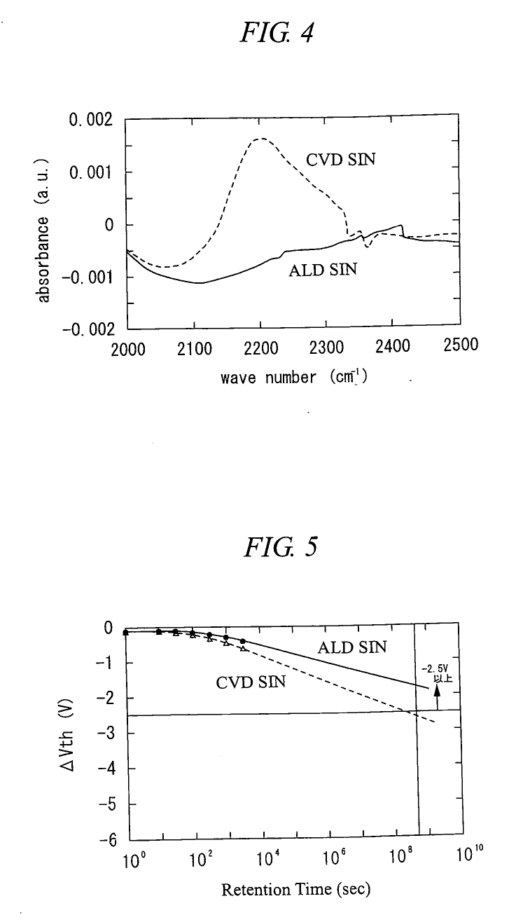

FIG. 4 shows an example of the residual hydrogen amount contained in each of the silicon nitride films formed by the CVD (CVD nitride film) and the silicon nitride film formed by the ALD (ALD nitride film). The longitudinal axis represents the absolute value and the horizontal axis represents the wavenumber. Since the energy of the Si—H appears in the wavenumber range of 2100 to 2300 cm⁻¹, the integral value in this range corresponds to the residual hydrogen amount in the nitride film. As is apparent from FIG. 4, the residual hydrogen amount in the ALD nitride film is smaller than that in the CVD nitride film, and the residual hydrogen amount can be reduced to about one-thirtieth.

More specifically, in the non-volatile memory which holds the data by storing the electrons in the charge storage layer CSL as described in this embodiment, it is necessary to reduce the hydrogen contained in the charge storage layer CSL.

FIG. 5 shows an example of the data retention characteristics of the memory cell in the case where the silicon nitride film formed by the CVD (CVD nitride film) and the silicon nitride film formed by the ALD (ALD nitride film) are used as the charge storage layers in the non-volatile memory operated at 50 MHz. The longitudinal axis represents the shift amount of the threshold voltage (AVth) and the horizontal axis represents the data retention time. Also, the hydrogen concentration in the CVD nitride film is about 10²¹ cm⁻³, and that in the ALD nitride film is about 10²⁰ cm⁻³ or less. The target of the data retention characteristics of the memory cell is 20 years and that of the shift amount of the threshold voltage is −2.5 V or less. However, since the extrapolation value of the shift amount of the threshold voltage is about −3.0 V, the memory cell using the CVD nitride film cannot achieve the target. On the other hand, since the extrapolation value of the shift amount of the threshold voltage is −2.0 V, the memory cell using the ALD nitride film can achieve the target.

As described above, when the silicon nitride film formed by the ALD is used to form the charge storage layer CSL, the hydrogen concentration can be reduced to 10²⁰ cm⁻³ or less and the variation of the threshold voltage can be reduced. Furthermore, since the hydrogen concentration in the charge storage layer CSL is reduced, the Si—H bond density in the charge storage layer CSL is reduced and the silicon dangling bond created by the emission of hydrogen from the Si—H bond is also reduced. Therefore, the shallow trap level is hardly formed. In this manner, since the conduction and diffusion of the electrons in the charge storage layers CSL of the same layer provided in each of the adjacent memory cells MC can be reduced, the variation of data in the memory cells MC1 can be reduced. Also, since the S—H bond density in the charge storage layer CSL is reduced, the hydrogen ions which cut the Si—O bonds in the insulator 6b are reduced and the defects are hardly created. As a result, the leakage path in the longitudinal direction is not created, and thus, the leakage current can be reduced.

An n-type semiconductor region 7 is formed in the main surface of the substrate 1 below the insulator 6b and between the p-type semiconductor region 4 and the source region Srm. This semiconductor region 7 is a semiconductor region for forming the channel of the memory nMIS Qnm, and the threshold voltage of the memory nMIS Qnm is set to a predetermined value by this semiconductor region 7. The semiconductor region 7 has a function to reduce the threshold voltage of the memory nMIS Qnm. For example, arsenic (As) or phosphorus (P) is introduced to the semiconductor region 7. A first layer wiring Ml extending in the direction orthogonal to the memory gate electrode MG (or control gate electrode CG) is connected to the drain region Drm via the plug PLG buried in the contact hole CNT.

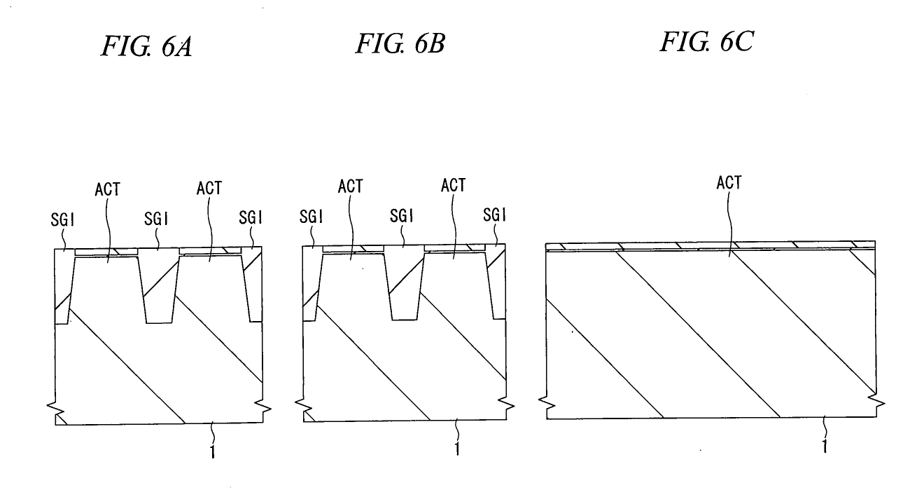

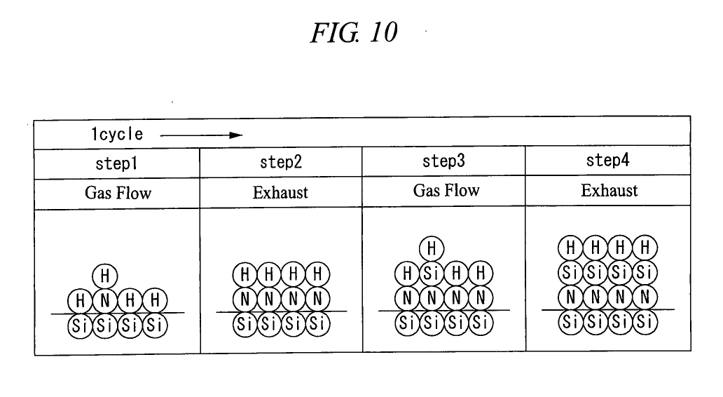

Next, an example of the manufacturing method of a semiconductor integrated circuit device will be described with reference to FIGS. 6A to 15C. FIGS. 6A to 9C and FIGS. 11A to 15C are sectional views showing the principal part of the semiconductor substrate in the memory region during the manufacturing process of the semiconductor integrated circuit device, and FIG. 10 is a schematic diagram for explaining the film-forming process of the nitride film formed by the ALD. The case where the present invention is applied to the memory cell MC1 in FIG. 2 is described here, and each of a to c in FIGS. 6A to 9C and FIGS. 11A to 15C shows the same position as those of FIGS. 3A to 3C, respectively.

First, as shown in FIGS. 6A-6C, trench device isolations SGI and active regions ACT surrounded by the trench device isolations SGI are formed on the main surface of the substrate (flat round semiconductor thin plate referred to as semiconductor wafer in this step) 1. More specifically, after forming isolation trenches in the predetermined positions of the substrate 1, an insulator made of, for example, silicon oxide is deposited on the main surface of the substrate 1, and then, the insulator is polished by the CMP (Chemical Mechanical Polishing) so as to leave the insulator only in the trenches. In this manner, the device isolations SGI are formed.

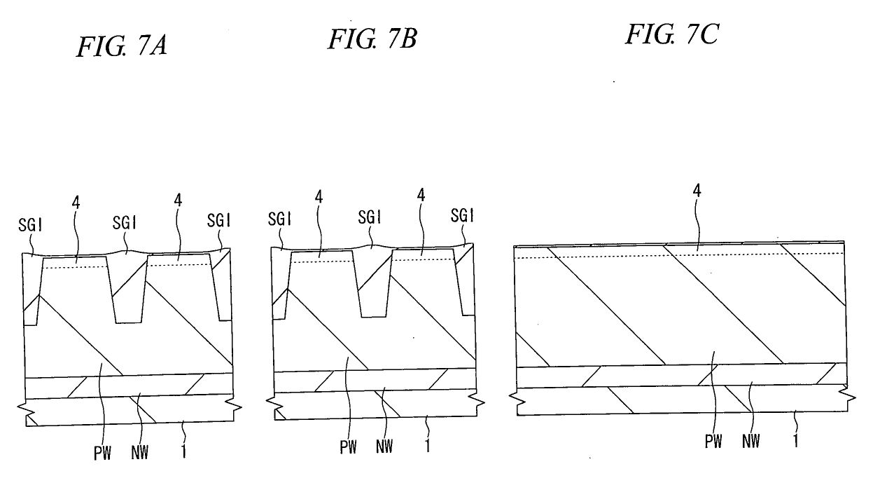

Next, as shown in FIGS. 7A-7C, a predetermined impurity is selectively introduced into the predetermined positions of the substrate 1 by the ion implantation with a predetermined energy. By doing so, a buried n well NW and a p well PW are formed. Subsequently, boron fluoride (BF₂) is introduced into the main surface of the substrate 1 by the ion implantation. By doing so, p-type semiconductor region 4 for forming the channel of the selecting nMIS Qnc is formed on the main surface of the substrate 1. The implantation energy of the impurity ion at this time is, for example, about 60 KeV and the dose amount is, for example, about 9×10¹² cm².

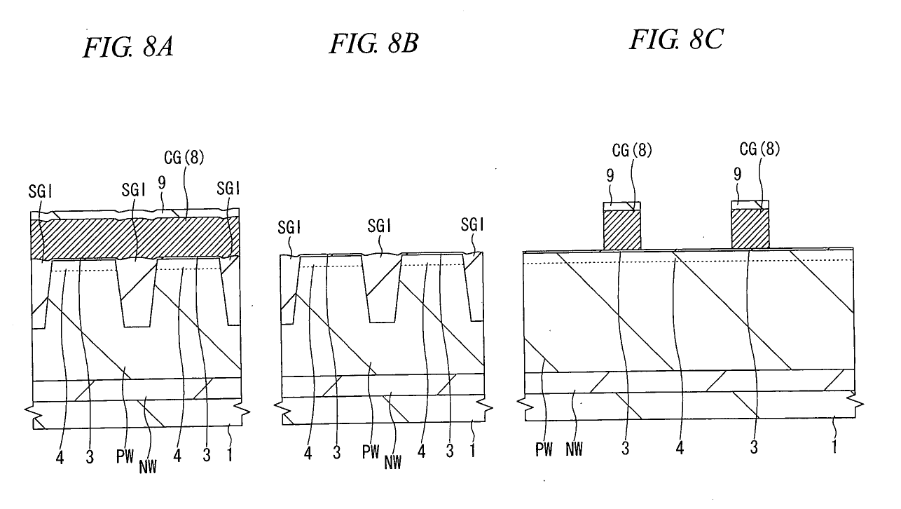

Next, as shown in FIGS. 8A-8C, after forming a gate insulator 3 made of, for example, silicon oxide with a thickness of about 2 to 3 nm on the main surface of the substrate 1 by the oxidation process to the substrate 1, a conductor film 8 made of, for example, low-resistance polysilicon with a thickness of about 200 nm is deposited on the main surface of the substrate 1 by the CVD, and then, a cap insulator 9 made of, for example, silicon oxide with a thickness of about 50 nm is deposited on the conductor film 8 by the CVD. Thereafter, the laminated film of the conductor film 8 and the cap insulator 9 is patterned by the lithography technique and the dry etching. By doing so, the control gate electrode CG is formed.

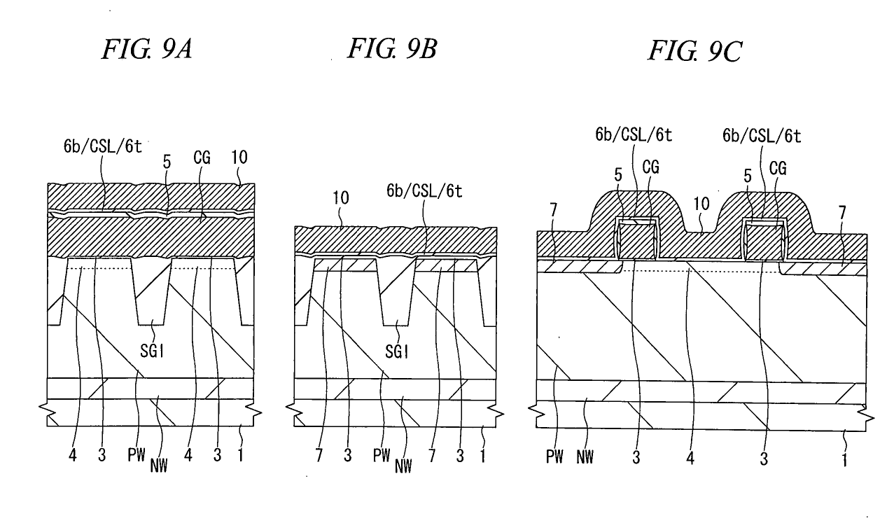

Next, as shown in FIGS. 9A-9C, after removing the cap insulator 9, an insulator 5 made of silicon oxide with a thickness of about 3 nm is formed on the exposed surface of the control gate electrode CG by the oxidation process to the substrate 1. Subsequently, arsenic or phosphorus is ion-implanted into the main surface of the substrate 1 with using the control gate electrode CG and the resist pattern as the masks. By doing so, the n-type semiconductor region 7 for forming the channel of the memory nMIS is formed. The impurity ion implantation energy at this time is, for example, about 20 to 40 KeV.

Next, the insulator 6b made of silicon oxide, the charge storage layer CSL made of silicon nitride, the insulator 6t made of silicon oxide, and the conductor film 10 for forming the memory gate made of low-resistance polysilicon are deposited in this order from below on the main surface of the substrate 1. The insulator 6b is formed by the thermal oxidation and has a thickness of, for example, about 6 nm, and the charge storage layer CSL is formed by the ALD and has a thickness of, for example, about 12 nm. The insulator 6t is formed by the CVD and has a thickness of, for example, about 5 nm, and the conductor film 11 is formed by the CVD and has a thickness of, for example, about 150 nm. Note that the laminated film of the insulator 6b, the charge storage layer CSL, and the insulator 6t is represented by 6b/CSL/6t. Also, since the insulator 6b is formed by the thermal oxidation, the insulator 6b is not formed on the device isolations SGI in FIGS. 9A and 9B.

The charge storage layer CSL can be formed in the following manner in accordance with the film-forming process of the nitride film by the ALD shown in FIG. 10.

First, after setting the temperature in the reactor of the ALD equipment to about 550° C., the NH₃ gas is introduced into the reactor and the NH₃ is decomposed by the remote plasma to form the N—H radical on the substrate (Si) (Step 1). Next, the gas in the rector is exhausted to completely discharge the NH₃ gas from the reactor (Step 2). Next, SiH₂Cl₂ gas is introduced into the reactor and the SiH₂Cl₂ is thermally decomposed to form the N-Si radical and further form the Si—H radical by the desorption of HCl (Step 3). Next, the gas in the reactor is exhausted to completely discharge the SiH₂Cl₂ gas from the reactor (Step 4). The steps 1 to 4 are set as one cycle, and the silicon nitride film constituting the charge storage layer CSL is formed by performing this cycle once or several times. Since the silicon nitride film with a thickness of about 0.115 nm is formed by one cycle, the number of cycles is determined depending on the desired thickness of the charge storage layer CSL. By the ADL as described above, the hydrogen concentration in the film can be reduced to 10²⁰ cm⁻³ or less. In addition, since the Si—H bond density in the film can be greatly reduced, it is possible to form the silicon nitride film in which the formation of the shallow trap level due to the Si—H bond density is reduced. Note that though NH₃ is used as an example of a material to form the N—H radical in the Step 1, N₂ or N₂H₄ is also available. In addition, though SiH₂Cl₂ is used as an example of a material to form the N—Si radical in the Step 3, the gas or the liquid of SiH₄, Si₂H₆, Si₂Cl₆, Si₂Cl₆, SiCl₄, and the BTBAS are also available.

As described above, when the charge storage layer CSL is formed by the ALD, it is possible to reduce the variation of the trap level of the electrons in the charge storage layers CSL of the same layer provided in each of the adjacent memory cells MC1. Therefore, the variation of the threshold voltage in the memory cells MC1 can be reduced and the data variation can be reduced. Simultaneously, since the S—H bond density in the charge storage layer CSL can be reduced, the hydrogen ions which cut the Si—O bonds in the insulator 6b are reduced and the defects are hardly formed. As a result, the leakage path in the longitudinal direction of the memory gate electrode is not created, and thus, the leakage current can be reduced.

Also, as shown in FIG. 9B, the charge storage layer CSL extends in the B-B′ direction of FIG. 2 and is formed in each of the memory cells MC1 arranged on the device isolations SGI along the B-B′ direction. As described above, the charge storage layer CSL is formed by the ALD. Therefore, since the conduction and diffusion of the electrons between the charge storage layers CSL of the same layer provided in each of the adjacent memory cells MC1 can be reduced, the data variation in each of the memory cells MC1 can be reduced.

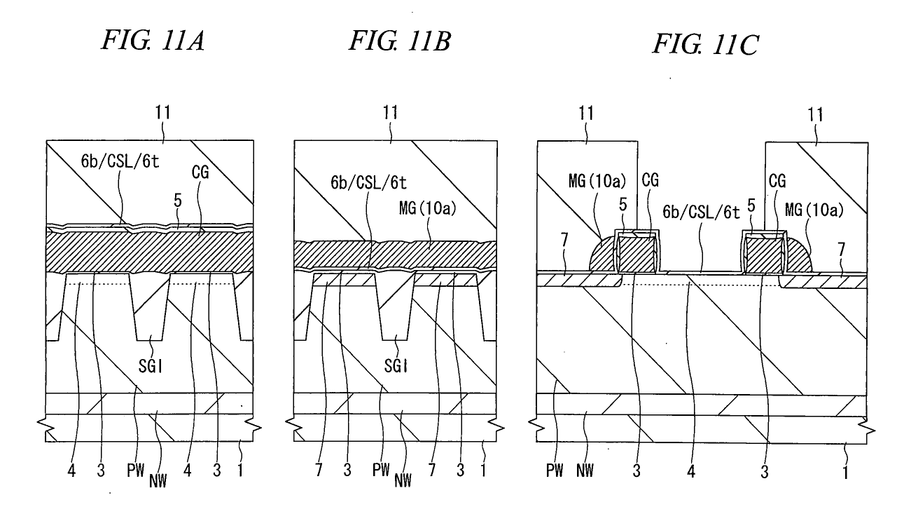

Next, as shown in FIGS. 11A-11C, the conductor film 10 is etched back by the anisotropic dry etching, thereby forming the sidewall 10a of the conductor film 10 on the side surface of the control gate electrode CG.

Next, a resist pattern 11 for forming the memory gate electrode MG is formed on the main surface of the substrate 1 by the lithography technique. Thereafter, the sidewall 10a exposed through the resist pattern 11 used as a mask is etched to form the memory gate electrode MG (sidewall 10a) on the one side surface of the control gate electrode CG.

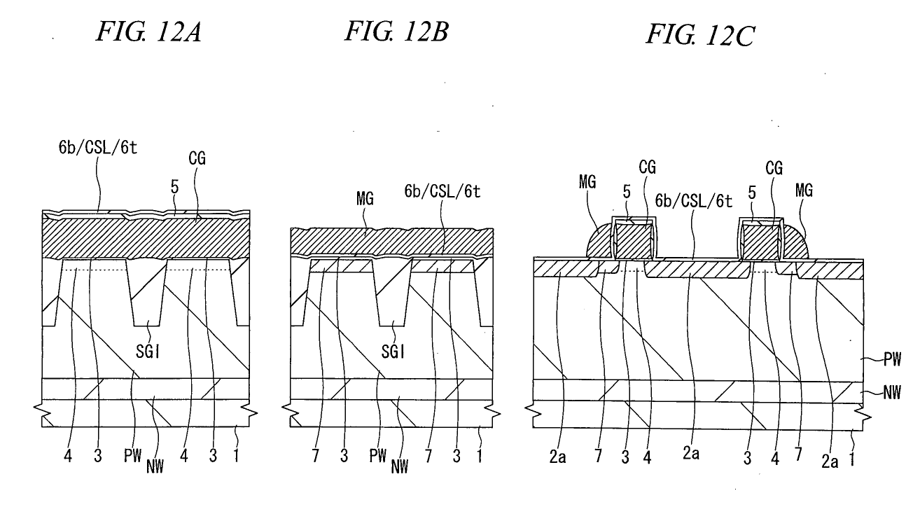

Next, as shown in FIGS. 12A-12C, after removing the resist pattern 11, arsenic or phosphorus is ion-implanted into the main surface of the substrate 1 with using the control gate electrode CG and the memory gate electrode MG as the masks. By doing so, an n⁻-type semiconductor region 2a is formed on the main surface of the substrate 1 in a self alignment manner with the control gate electrode CG and the memory gate electrode MG.

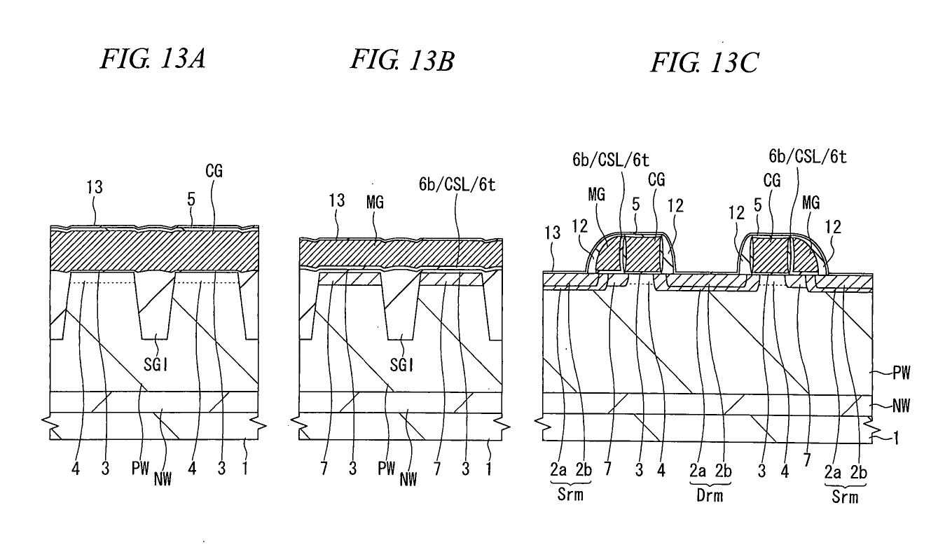

Next, as shown in FIGS. 13A-13C, the insulators 6b and 6t and the charge storage layer CSL are selectively etched, thereby patterning the charge storage layer CSL. Subsequently, an insulator made of, for example, silicon oxide with a thickness of about 100 nm is deposited on the main surface of the semiconductor substrate 1 by the CVD. Thereafter, the insulator is etched back by the anisotropic dry etching. By doing so, a sidewall 12 is formed on the one side surface of the control gate electrode CG and on the memory gate electrode MG. Subsequently, after an insulator 13 made of, for example, silicon oxide is deposited on the main surface of the substrate 1 by the CVD, arsenic or phosphorus is ion-implanted into the main surface of the substrate 1 with using the sidewall 12 and the memory gate electrode MG as the masks. By doing so, an n⁺-type semiconductor region 2b is formed on the main surface of the substrate 1 in a self alignment manner with the control gate electrode CG and the memory gate electrode MG. In this manner, the drain region Drm and the source region Srm of the memory cell MC1 are formed and the selecting nMIS Qnc and the memory nMIS Qnm are formed.

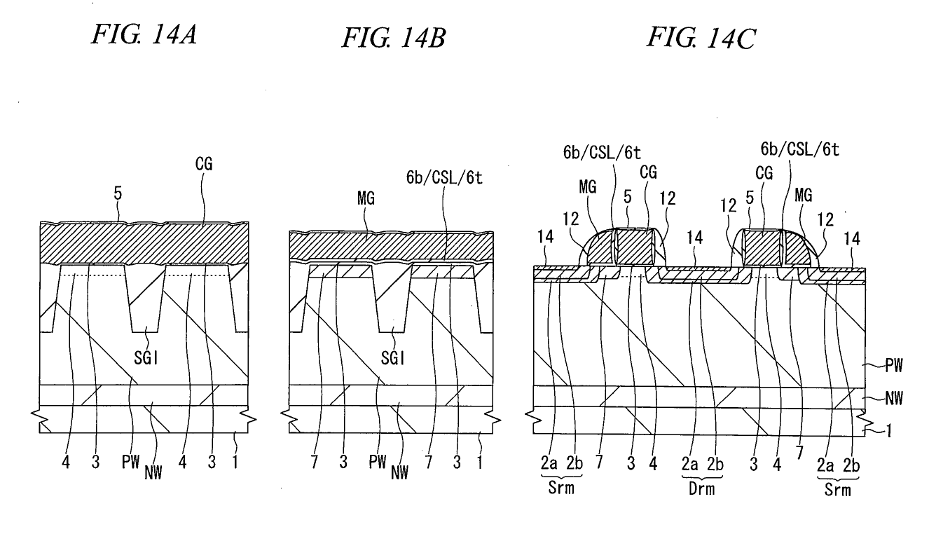

Next, as shown in FIGS. 14A-14C, after removing the insulator 13, a silicide layer 14 such as cobalt silicide (CoSix) is formed on the main surface of the substrate 1 by the Salicide (Self Align silicide) process.

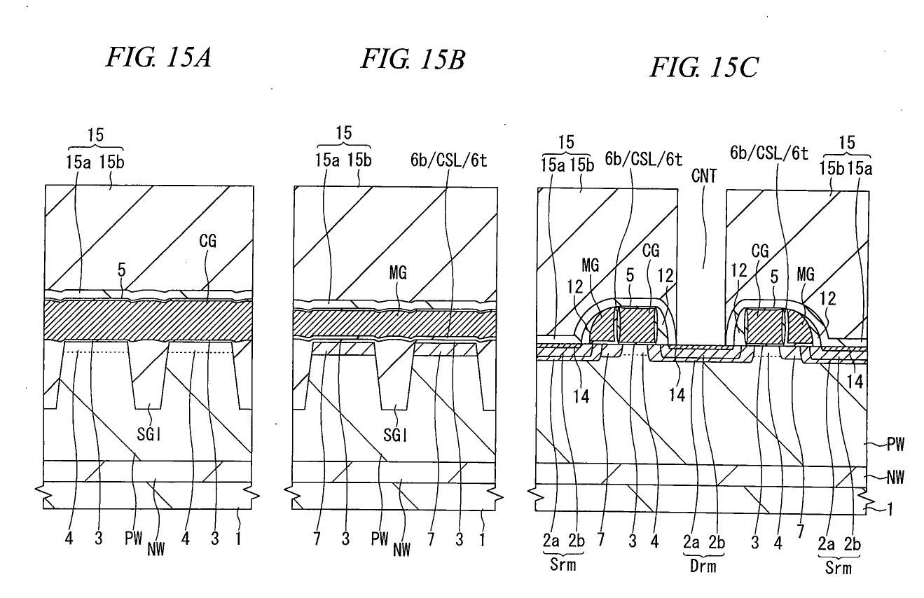

Next, as shown in FIGS. 15A-15C, after an insulator 15 comprised of a silicon nitride film 15a and a silicon oxide film 15b is deposited on the main surface of the substrate 1 by the CVD, a contact hole CNT is formed in the insulator 15. Subsequently, a plug PLG is formed in the contact hole CNT. The plug PLG includes a relatively thin barrier film comprised of a laminated film of titanium (Ti) and titanium nitride (TiN) and a relatively thick conductor film made of tungsten (W) or aluminum (Al) surrounded by the barrier film. Thereafter, a first layer wiring Ml made of, for example, tungsten or aluminum is formed on the insulator 15. By doing so, the memory cell MC1 shown in FIG. 3 is almost completed. Thereafter, the semiconductor integrated circuit device having the non-volatile memory is manufactured through the usual manufacturing process of the semiconductor integrated circuit device.

### Second Embodiment

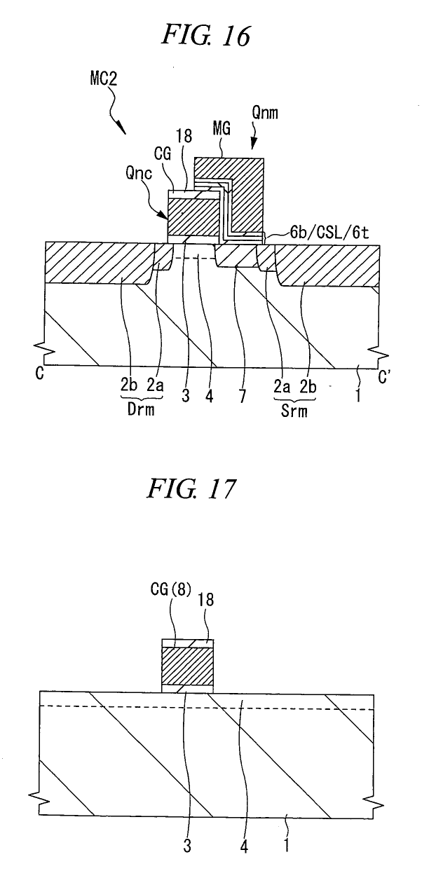

In the second embodiment, the case where the present invention is applied to the memory cell having the memory gate electrode formed on the top of the control gate will be described. FIG. 16 shows an example of the basic device section of the memory cell obtained by cutting the channel along the direction orthogonal to the memory gate electrode MG (C-C′ direction in FIG. 2). The two memory cells arranged in the C-C′ direction are illustrated in the first embodiment. However, only one memory cell is illustrated in the second embodiment for the simplification of the description.

The memory cell MC2 having the memory gate electrode formed on the top of the gate has the planar structure almost identical to that of the memory cell MC1 in the first embodiment. However, in the sectional structure, a part of the memory gate electrode MG is formed on the control gate electrode CG, and the control gate electrode CG and the memory gate electrode MG are isolated from each other by the insulator 18 made of silicon oxide, the insulators 6b and 6t, and the charge storage layer CSL on the upper surface of the control gate electrode CG.

Next, a concrete example of the manufacturing method thereof will be described with reference to FIGS. 17 to 20 each showing the principal part of the semiconductor substrate in the memory region in the manufacturing process of the semiconductor integrated circuit device.

First, after the processes identical to those described in the first embodiment with reference to FIGS. 6A-6C and 7A-7C, the oxidation process to the substrate 1 is performed to form the gate insulator 3 made of, for example, silicon oxide on the main surface of the substrate 1 as shown in FIG. 17. Furthermore, the conductor film 8 made of, for example, low-resistance polysilicon is deposited on the main surface of the substrate 1 by the CVD, and the insulator 18 made of, for example, silicon oxide is deposited on the conductor film 8 by the CVD. Thereafter, the laminated film of the gate insulator 3, the conductor film 8, and the insulator 18 is patterned by the lithography technique and the dry etching technique. By doing so, the control gate electrode CG is formed.

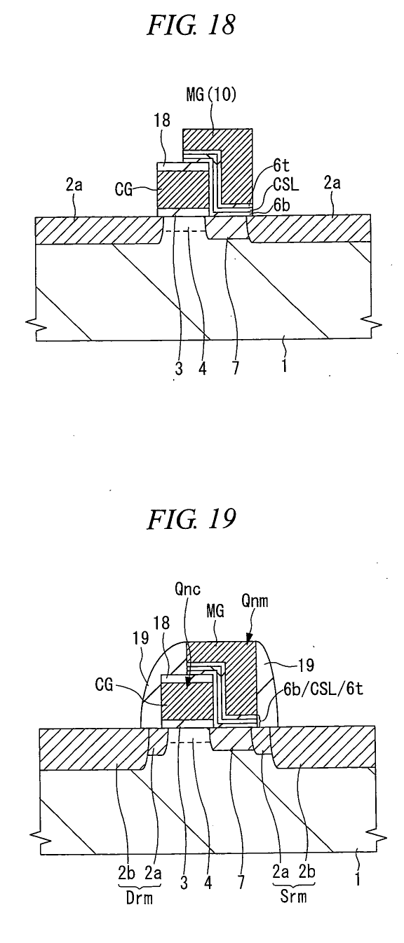

Next, as shown in FIG. 18, the n-type semiconductor region 7 for forming the channel of the memory nMIS is formed with using the control gate electrode CG as a mask. Subsequently, after depositing the insulator 6b, the charge storage layer CSL, the insulator 6t, and the conductor film 10 for forming the memory gate on the main surface of the substrate 1 in this order from below, these films are patterned by the lithography technique and the dry etching technique. By doing so, the memory gate electrode MG, a part of which is formed on the top of the control gate electrode CG, is formed. Similar to the charge storage layer CSL described in the first embodiment, the charge storage layer CSL is formed by the ADL and the hydrogen concentration thereof is reduced to 10²⁰ cm⁻³ or less. Subsequently, arsenic or phosphorus is ion-implanted into the main surface of the substrate 1 with using the control gate electrode CG and the memory gate electrode MG as the masks. By doing so, the n⁻-type semiconductor region 2a is formed on the main surface of the substrate 1 in the self alignment manner with the control gate electrode CG and the memory gate electrode MG.

Next, as shown in FIG. 19, an insulator made of, for example, silicon oxide is deposited on the main surface of the substrate 1 by the CVD. Thereafter, the insulator is etched back by the anisotropic dry etching. By doing so, the sidewall 19 is formed on one side surface of the control gate electrode CG and on both side surfaces of the memory gate electrode MG. Subsequently, arsenic or phosphorus is ion-implanted into the main surface of the substrate 1 with using the sidewalls 19 and the memory gate electrode MG as the masks, thereby forming the n⁺-type semiconductor region 2b on the main surface of the substrate 1 in the self alignment manner with the control gate electrode CG and the memory gate electrode MG. In this manner, the drain region Drm and the source region Srm of the memory cell MC2 are formed, and the selecting nMIS Qnc and the memory nMIS Qnm are formed.

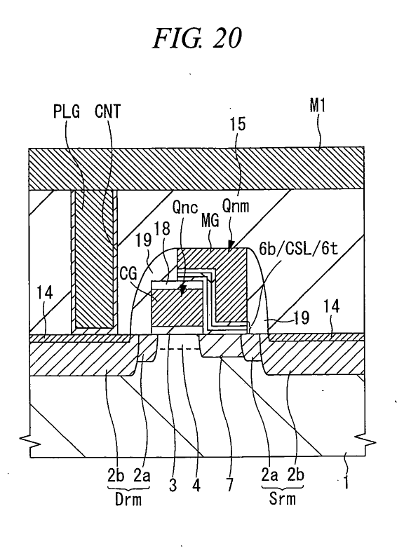

Thereafter, similar to the first embodiment, the silicide layer 14 is formed on the main surface of the substrate 1 and on the upper surface of the control gate electrode CG through the salicide process as shown in FIG. 20. Then, the memory cell MC2 is manufactured through the deposition process of the insulator 15, the forming process of the contact hole CNT, the forming process of the plug PLG, and the forming process of the first layer wiring M1.

As described above, according to the second embodiment, since it is possible to reduce the hydrogen concentration in the charge storage layer CSL provided in the memory cell MC2 having the memory gate electrode formed on a top of the control gate, the variation of the threshold voltage can be reduced and the data variation in the memory cell MC2 can be reduced similarly to the memory cell MC1 in the first embodiment. In addition, since the defects are hardly formed in the insulator 6b, the leakage path in the longitudinal direction is not formed, and thus, the leakage current can be reduced. Also, similar to the first embodiment, the charge storage layer CSL extends in the direction orthogonal to the C-C′ direction in FIG. 2 and is formed on the device isolations SGI and in each of the adjacent memory cells MC2 arranged in the direction orthogonal to the direction D-D′. Therefore, since the conduction and diffusion of the electrons between the charge storage layers CSL of the same layer provided in each of the adjacent memory cells MC2 can be reduced, the data variation in each memory cell MC2 can be reduced.

### Third Embodiment

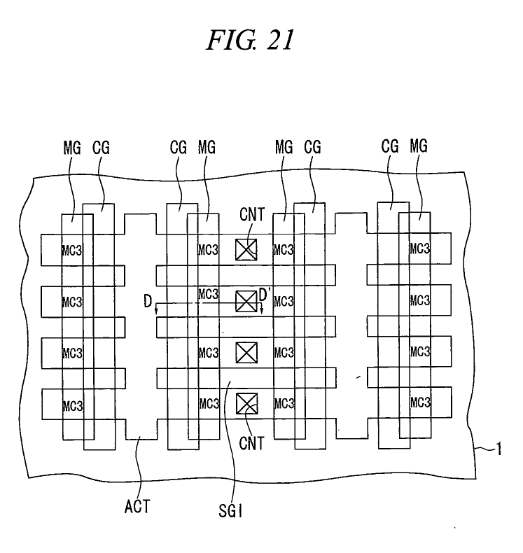

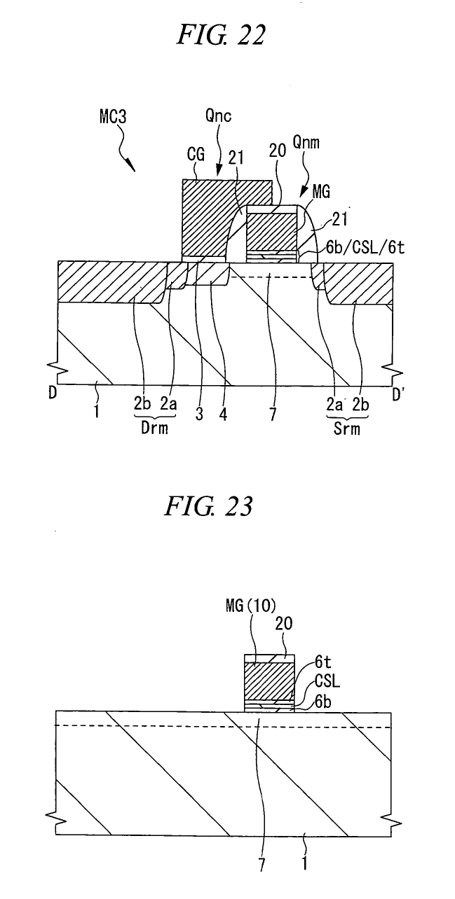

In this third embodiment, the case where the present invention is applied to the memory cell having the control gate electrode formed on the top of the memory gate will be described. FIG. 21 is a plan view showing the principal part of the memory cell, and FIG. 22 shows an example of the basic device section of the memory cell obtained by cutting the channel along the direction orthogonal to the memory gate electrode (line D-D′ in FIG. 21).

A selecting nMIS Qnc and a memory nMIS Qnm of the memory cell MC3 are arranged in the active region ACT on the main surface of the substrate 1. The control gate electrode CG of the selecting nMIS Qnc and the memory gate electrode MG of the memory nMIS Qnm adjacently extend between the drain region Drm and the source region Srm of this memory cell MC3 on the main surface of the substrate 1, and a part of the control gate electrode CG is formed on the top of the memory gate electrode MG. Also, similar to the memory cell MC1 in the first embodiment, a plurality of memory cells MC3 are adjacently arranged via the device isolations SGI,formed in the substrate 1 along the extending direction of the memory gate electrode MG (or control gate electrode CG).

The gate insulator 3 made of silicon oxide is formed between the control gate electrode CG and the main surface of the substrate 1. The semiconductor region 4 for forming the channel of the selecting nMIS Qnc is formed below the gate insulator 3 on the main surface of the substrate 1. Meanwhile, the charge storage layer CSL sandwiched between the upper and lower insulators 6b and 6t is provided between the memory gate electrode MG and the main surface of the substrate 1. The charge storage layer CSL is made of silicon nitride and is formed by the ADL similar to that described in the first embodiment.

The semiconductor region 7 for forming the channel of the memory nMIS Qnm is formed below the insulator 6b between the p-type semiconductor region 4 and the source region Srm on the main surface of the substrate 1. Furthermore, an insulator 20 made of, for example, silicon oxide is formed on the upper surface of the memory gate electrode MG. Also, the sidewall 21 made of, for example, silicon oxide is formed on the side surfaces of the memory gate electrode MG, the insulators 6b and 6t, and the charge storage layer CSL, and the memory gate electrode MG and the control gate electrode CG are isolated from each other by the insulator 20 and the sidewall 21.

Next, a concrete example of the manufacturing method thereof will be described with reference to FIGS. 23 to 27 each showing the principal part of the semiconductor substrate in the memory region in the manufacturing process of the semiconductor integrated circuit device.

First, after the processes identical to those described in the first embodiment with reference to FIGS. 6A-6C and 7A-7C, the n-type semiconductor region 7 for forming the channel of the memory nMIS is formed in the active region ACT on the main surface of the substrate 1. Subsequently, as shown in FIG. 23, the insulator 6b made of silicon oxide, the charge storage layer CSL made of silicon nitride, the insulator 6t made of silicon oxide, the conductor film 10 for forming the memory gate made of low-resistance polysilicon, and the insulator 20 made of silicon oxide are formed in this order from below on the main surface of the substrate 1. Thereafter, the laminated film thereof is patterned by the photolithography technique and the etching technique, thereby forming the memory gate electrode MG. The charge storage layer CSL is formed by the ADL similar to that described in the first embodiment, and the hydrogen concentration thereof is reduced to 10²⁰ cm⁻³.

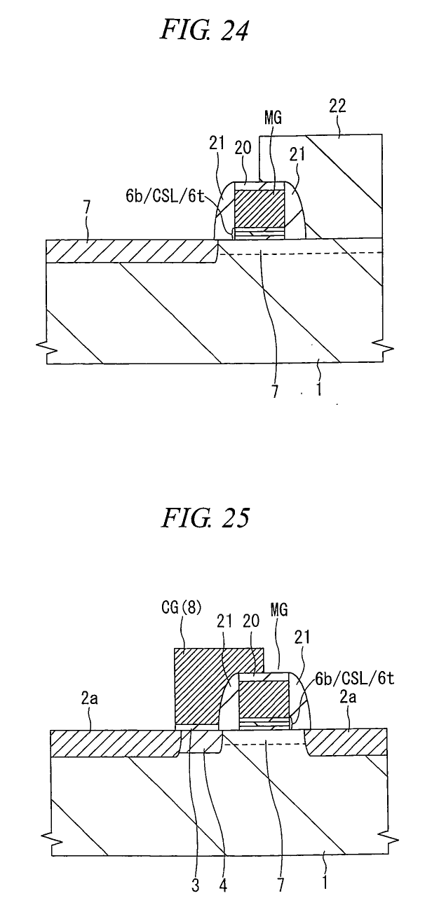

Next, as shown in FIG. 24, after an insulator made of, for example, silicon oxide is deposited on the main surface of the substrate 1 by the CVD, the insulator is etched back by the anisotropic dry etching, thereby forming the sidewall 21 on the side surface of the laminated pattern. Subsequently, boron fluoride is ion-implanted into the main surface of the substrate 1 with using the control gate electrode CG, the sidewall 21, and the resist pattern 22 as the masks. By doing so, the p-type semiconductor region 4 for forming the channel of the selecting nMIS is formed.

Next, as shown in FIG. 25, after forming the gate insulator 3 made of, for example, silicon oxide on the main surface of the substrate 1 by the oxidation process to the substrate 1, a conductor film 8 made of, for example, low-resistance polysilicon is deposited on the main surface of the substrate 1 by the CVD, and then, the conductor film 8 is patterned by the lithography technique and the dry etching technique. By doing so, the control gate electrode CG is formed. Subsequently, arsenic or phosphorus is ion-implanted into the main surface of the substrate 1 with using the control gate electrode CG and the memory gate electrode MG as the masks, thereby forming the n⁻-type semiconductor region 2a on the main surface of the substrate 1 in the self alignment manner with the control gate electrode CG and the memory gate electrode MG.

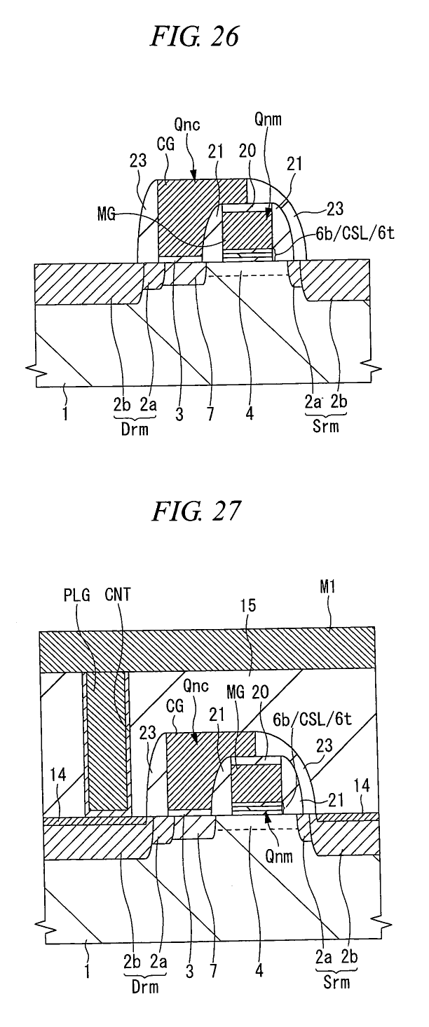

Next, as shown in FIG. 26, after an insulator made of, for example, silicon oxide is formed on the main surface of the substrate 1, the insulator is etched back by the anisotropic dry etching, thereby forming the sidewalls 23 on both side surfaces of the control gate electrode CG, on the insulator 20 and on the surface of the sidewall 21. Subsequently, arsenic or phosphorus is ion-implanted into the main surface of the substrate 1 with using the sidewall 23 and the control gate electrode CG as the masks, thereby forming the n⁺-type semiconductor region 2b on the main surface of the substrate 1 in the self alignment manner with the control gate electrode CG and the memory gate electrode MG. In this manner, the drain region Drm and the source region Srm of the memory cell MC3 are formed, and the selecting nMIS Qnc and the memory nMIS Qnm are formed.

Thereafter, as shown in FIG. 27, the silicide layer 14 is formed on the main surface of the substrate 1 and on the upper surface of the control gate electrode CG through the salicide process similar to that of the first embodiment. Thereafter, after the deposition process of the insulator 15, the forming process of the contact hole CNT, the forming process of the plug PLG, and the forming process of the first layer wiring Ml, the memory cell MC3 is manufactured.

As described above, according to the third embodiment, since it is possible to reduce the hydrogen concentration in the charge storage layer CSL provided in the memory cell MC3 having the control gate electrode formed on a top of the memory gate, the variation of the threshold voltage can be reduced and the data variation in the memory cell MC3 can be reduced similarly to the memory cell MC1 in the first embodiment. In addition, since the defects are hardly created in the insulator 6b, the leakage path in the longitudinal direction is not created, and thus, the leakage current can be reduced. Also, the charge storage layer CSL extends in the direction orthogonal to the D-D′ direction in FIG. 21 and is formed on the device isolations SGI and in each of the adjacent memory cells MC3 arranged in the direction orthogonal to the direction D-D′. Therefore, since the conduction and diffusion of the electrons between the charge storage layers CSL of the same layer provided in each of the adjacent memory cells MC3 can be reduced, the data variation in each of the memory cells MC3 can be reduced.

### Fourth Embodiment

In this fourth embodiment, the case where the present invention is applied to the memory cell of the NROM (Nitride Read-Only Memory) which is a kind of the non-volatile memory will be described.

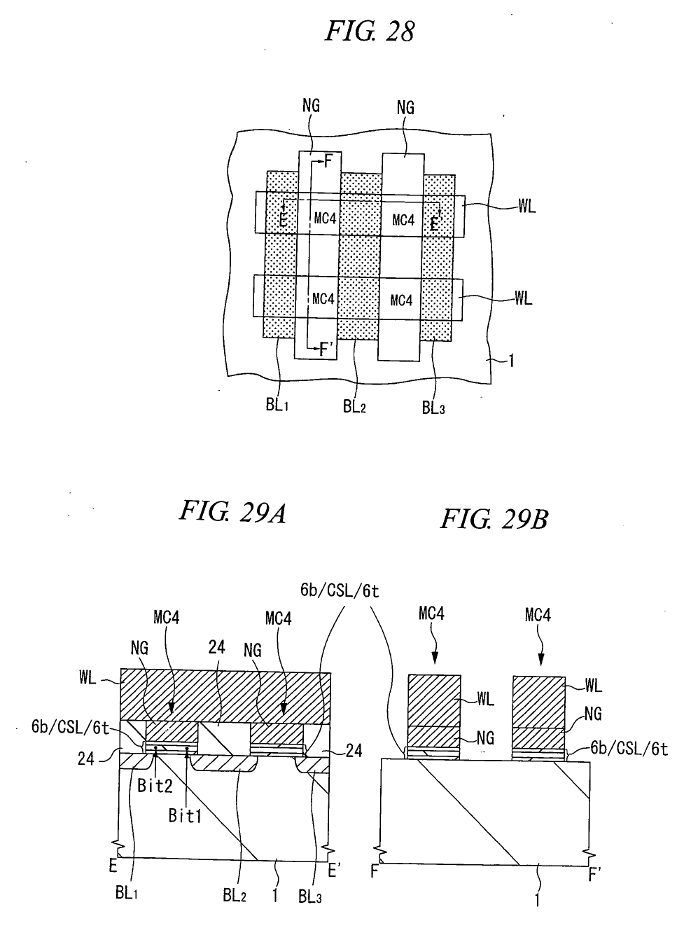

FIG. 28 is a plan view showing the principal part of the memory cell, FIG. 29A is a sectional view showing the principal part of the memory cell obtained by cutting the word line along its extending direction (line E-E′ in FIG. 28), and FIG. 29B is a sectional view showing the principal part of the memory cell obtained by cutting along the direction orthogonal to the word line (line F-F′ in FIG. 28). The two bits of the memory cells arranged in both directions are shown here.

The nMIS (third field effect transistor) Qng are arranged in a matrix on the main surface of the substrate 1. The bit lines (shown by the hatching in FIG. 28) BL₁ to BL₃ are arranged in parallel to each other in one direction, for example, the column direction on the substrate 1. The bit lines BL₁ to BL₃ are comprised of, for example, the n⁺-type semiconductor regions. The charge storage layer CSL sandwiched between the insulators 6n and 6t is provided each between the bit lines BL₁ and BL₂ and between the bit lines BL₂ and BL₃ on the main surface of the substrate 1. The charge storage layer CSL is made of, for example, silicon nitride and has a thickness of, for example, about 10 nm. Also, the charge storage layer CSL is formed by the ALD. The insulators 6b and 6t are made of, for example, silicon oxide and have a thickness of, for example, about 5 nm.

The gate electrodes (third gate electrode) NG are formed on the insulator 6t, and the word lines WL extending in the direction orthogonal to the extending direction of the bit lines BL₁ to BL₃, for example, the row direction are connected to the gate electrodes NG. The word line WL is made of, for example, low-resistance polysilicon and its thickness is about 250 nm. The memory cells MC4 arranged in the extending direction of the word line WL are electrically isolated from each other by the insulator 24.

Next, an example of the operation of the memory cell MC4 will be described in brief with reference to FIGS. 29A and 29B.

The memory cell MC4 of the NROM can store the two-bit data in one transistor. When writing the data, the voltage of, for example, about 9 V is applied to the word line (commonly used in the two bits) WL and the voltage of, for example, about 2.5 V is applied to the bit line BL₂, and also, the bit line BL₁ is set to, for example, 0 V. By doing so, the electrons corresponding to the initial bit (Bit 1) can be stored in the charge storage layer CSL. When reading the data, the voltage of, for example, about 3 V is applied to the word line WL. Then, the bit line BL₂ is set to, for example, 0 V and the voltage of, for example, about 1.5 V is applied to the bit line BL₁. By doing so, the bit (Bit 1) can be read. When the next bit (Bit 2) is written to and read from the memory cell MC4, the voltage applied to the bit lines BL₁ and BL₂ are exchanged.

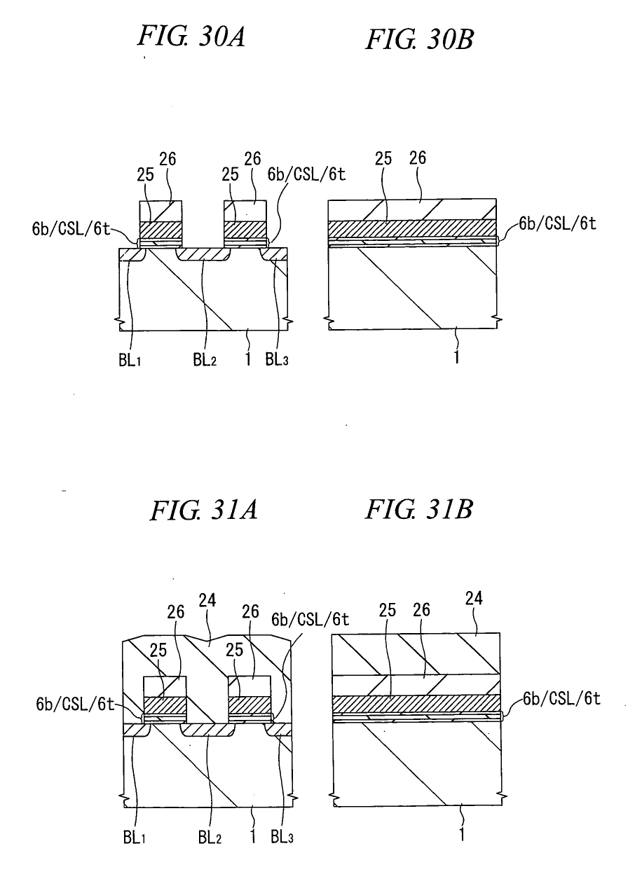

Next, a concrete example of the manufacturing method will be described with reference to FIGS. 30A to 33C which are the sectional views showing the principal part of the semiconductor substrate in the memory region in the manufacturing process of the semiconductor integrated circuit device.

First, as shown in FIGS. 30A and 30B, the insulator 6b made of, for example, silicon oxide with a thickness of about 5 nm is formed on the main surface of the substrate 1 by the oxidation process to the substrate 1, and then, the charge storage layer CSL made of silicon nitride, the insulator 6t made of silicon oxide, the conductor film 25 made of undoped polysilicon, and the silicon nitride film 26 are formed in this order from below. The charge storage layer CSL is formed by the ADL similar to that described in the first embodiment and has a thickness of, for example, about 10, nm and the hydrogen concentration thereof is reduced to 10²⁰ cm⁻³ or less. The insulator 6t is formed by the thermal oxidation and has a thickness of, for example, about 5 nm. Also, the undoped polysilicon film 24 is formed by the CVD and has a thickness of, for example, about 80 nm, and the silicon nitride film 25 is formed by the CVD and has a thickness of, for example, about 140 nm.

Next, this laminated film is etched by the lithography technique and the dry etching technique. Subsequently, arsenic or phosphorus is ion-implanted into the main surface of the substrate 1 with using the processed laminated film as the masks, thereby forming the n⁺-type semiconductor region constituting the bit lines BL₁ to BL₃ on the main surface of the substrate 1 in the self alignment manner with the laminated films.

Next, as shown in FIGS. 31A and 31B, the insulator 24 with a thickness of about 300 nm is deposited on the main surface of the substrate 1. The TEOS oxide film deposited by the plasma CVD using TEOS (Tetra Ethly Ortho Silicate: Si(OC₂H₅)₄) and ozone (O₃) as the source gas is used as the insulator 24. Alternately, it is also possible to deposit the insulator 24 by the coating method so as to effectively bury the space between the memory cells MC4.

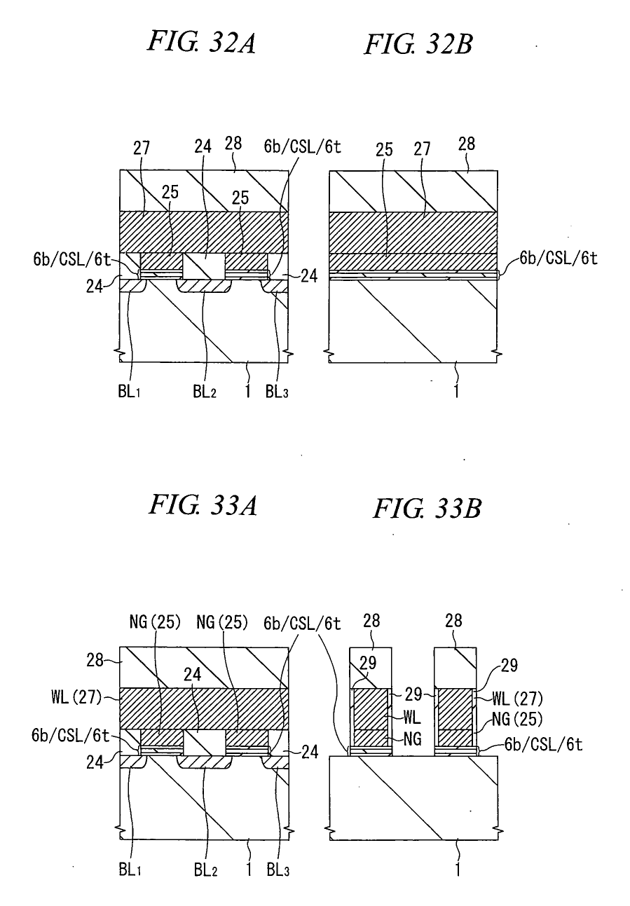

Next, as shown in FIGS. 32A and 32B, the insulator 24 is polished by the CMP to leave the insulator 24 between the laminated films. At this time, the silicon nitride film 26 functions as the polishing stopper. As described above, the adjacent memory cells MC4 arranged along the line E-E′ are isolated from each other by the insulator 24 buried between the nMIS transistors Qng. In this case, it is possible to process the memory cell more finely in comparison to the case where the space between the nMIS transistors Qng is isolated by the LOCOS method.

Subsequently, after removing the silicon nitride film 26 by using the thermal phosphoric acid, a conductor film 27 made of, for example, low-resistance polysilicon with a thickness of about 150 nm is deposited on the main surface of the substrate 1 by the CVD. By doing so, the conductor film 25 and the conductor film 27 are integrally connected. Furthermore, an insulator 28 made of, for example, silicon oxide with a thickness of about 150 nm is deposited on the conductor film 27 by the CVD.

Next, as shown in FIGS. 33A and 33B, the laminated film (the insulators 6b and 6t, the charge storage layer CSL, and the conductor film 25), the conductor film 27, and the insulator 28 are etched by the lithography technique and the dry etching technique. In this manner, the word lines are formed and separated from each other. Thereafter, an oxide film 29 is formed on the sidewall of the word line WL. By doing so, the memory cell MC4 shown in FIG. 28 is almost completed.

Note that it is also possible to form a silicide layer such as a cobalt silicide by the salicide process on the surface of the n⁺-type semiconductor region constituting the bit lines BL₁ and BL₂. By doing so, it is possible to reduce the bit line resistance.

As described above, according to the fourth embodiment, the hydrogen concentration in the charge storage layer CSL provided in the NROM is reduced, and the S—H bond density in the silicon nitride film is reduced. Therefore, hydrogen ions which cut the Si—O bonds in the insulator 6b are reduced and the defects are hardly formed. As a result, the leakage path in the longitudinal direction is not created, and thus, the leakage current can be reduced.

In the foregoing, the invention made by the inventor of the present invention has been concretely described based on the embodiments. However, it is needless to say that the present invention is not limited to the foregoing embodiments and various modifications and alterations can be made within the scope of the present invention.

For example, the case where the present invention is applied to the memory cell with the MONOS structure has been described in the foregoing embodiments. However, it is also possible to apply the present invention to the memory cell with the MNOS (Metal Nitride Oxide Semiconductor) structure in which a silicon oxide film, a silicon nitride film (or silicon oxynitride film) used for the charge storage, and a low-resistance polysilicon film are laminated in this order from below on the substrate.

The effect obtained by the typical ones of the embodiments disclosed in this application will be briefly described as follows.

A nitride film formed by the ALD is used to form the charge storage layer to reduce the hydrogen concentration in the charge storage layer to 10²⁰ cm⁻³ or less. Therefore, it is possible to reduce the variation of trap level of the electrons in the charge storage layer CSL of the memory cell, and also to reduce the S—H bond density. As a result, the variation of the threshold voltage of the memory cell MC1 can be reduced and thus the data variation can be reduced.

In addition, since it is possible to reduce the data variation between the adjacent memory cells and also to reduce the leakage current to the substrate, the reliability, more particularly, the data retention characteristics can be improved in the semiconductor integrated circuit device having the non-volatile memory using a nitride film as the charge storage layer.

The effect obtained by the typical ones of the inventions disclosed in this application will be briefly described as follows.

It is possible to improve the reliability of the semiconductor integrated circuit device having the non-volatile memory using a nitride film as the charge storage layer, more particularly, the data retention characteristics can be improved.

1. A manufacturing method of a semiconductor integrated circuit device which comprises a non-volatile memory cell including a first field effect transistor in a first region on a main surface of a semiconductor substrate and a second field effect transistor adjacent to said first field effect transistor in a second region, comprising the steps of:
(a) forming a first insulator on said first region;
(b) forming a first gate electrode of said first field effect transistor on said first region via said first insulator;
(c) forming a second insulator on said second region;
(d) forming a charge storage layer of said second field effect transistor so as to have hydrogen concentration of 10²⁰ cm⁻³ or less over said second region via said second insulator;
(e) forming a second gate electrode of said second field effect transistor above said second region via said second insulator and said charge storage layer; and
(f) implanting an impurity into a region adjacent to said first field effect transistor and said second field effect transistor, thereby forming an impurity region of a first conductivity type.

2. The manufacturing method of a semiconductor integrated circuit device according to claim
wherein said charge storage layer includes a silicon nitride film.

3. The manufacturing method of a semiconductor integrated circuit device according to claim 1,
wherein said non-volatile memory cell stores electrons in said charge storage layer and holds the data.

4. The manufacturing method of a semiconductor integrated circuit device according to claim 1, further comprising the step of: forming a third insulator between said charge storage layer and said second gate electrode.

5. A manufacturing method of a semiconductor integrated circuit device which comprises a non-volatile memory cell including a first field effect transistor in a first region on a main surface of a semiconductor substrate and a second field effect transistor adjacent to said first field effect transistor in a second region, comprising the steps of:
(a) forming a first insulator on said first region;
(b) forming a first gate electrode of said first field effect transistor on said first region via said first insulator;
(c) forming a second insulator on said second region;
(d) forming a charge storage layer of said second field effect transistor by Atomic Layer Deposition over said second region via said second insulator;
(e) forming a second gate electrode of said second field effect transistor above said second region via said second insulator and said charge storage layer; and
(f) implanting an impurity into a region adjacent to said first field effect transistor and said second field effect transistor, thereby forming an impurity region of a first conductivity type.

6. The manufacturing method of a semiconductor integrated circuit device according to claim 5,
wherein said charge storage layer includes a silicon nitride film.

7. The manufacturing method of a semiconductor integrated circuit device according to claim 5, further comprising the step of: forming a third insulator between said charge storage layer and said second gate electrode.

8. The manufacturing method of a semiconductor integrated circuit device according to claim 5,
wherein said non-volatile memory cell stores electrons in said charge storage layer and holds the data.

9. A manufacturing method of a semiconductor integrated circuit device which comprises a plurality of non-volatile memory cells each including a first field effect transistor in a first region on a main surface of a semiconductor substrate and a second field effect transistor adjacent to said first field effect transistor in a second region, said non-volatile memory cells being arranged adjacently via device isolations formed in said semiconductor substrate, comprising the steps of:
(a) forming a first insulator on each of said first regions of said plurality of non-volatile memory cells;
(b) forming a first gate electrode of said first field effect transistor on each of said first regions of said plurality of non-volatile memory cells via said first insulator;
(c) forming a second insulator on each of said second regions of said plurality of non-volatile memory cells;
(d) forming a charge storage layer of said second field effect transistor over said device isolations and over each of said second regions of said plurality of non-volatile memory cells via said second insulator so as to have hydrogen concentration of 10²⁰ cm⁻³ or less;
(e) forming a second gate electrode of said second field effect transistor above said device isolations and on each of said second regions of said plurality of non-volatile memory cells via said second insulator and said charge storage layer; and
(f) implanting an impurity into a region adjacent to said first field effect transistor and said second field effect transistor in each of said plurality of non-volatile memory cells, thereby forming an impurity region of a first conductivity type.

10. The manufacturing method of a semiconductor integrated circuit device according to claim 9,
wherein said charge storage layer includes a silicon nitride film.

11. The manufacturing method of a semiconductor integrated circuit device according to claim 9, further comprising the step of: forming a third insulator between said charge storage layer and said second gate electrode.

12. The manufacturing method of a semiconductor integrated circuit device according to claim 9,
wherein said plurality of non-volatile memory cells store electrons in said charge storage layers and holds the data.

13. A manufacturing method of a semiconductor integrated circuit device which comprises a non-volatile memory cell including a third field effect transistor which extends on a main surface of a semiconductor substrate and has a third gate electrode arranged between adjacent bit lines, comprising the steps of:
(a) forming a second insulator on the main surface of said semiconductor substrate;
(b) forming a charge storage layer between said adjacent bit lines over the main surface of said semiconductor substrate via said second insulator so as to have hydrogen concentration of 10²⁰ cm⁻³ or less;
(c) forming said third gate electrode between said adjacent bit lines on the main surface of said semiconductor substrate via said second insulator and said charge storage layer; and
(d) forming an impurity into said semiconductor substrate adjacent to said third electrode, thereby forming said bit lines.

14. The manufacturing method of a semiconductor integrated circuit device according to claim 13,
wherein said charge storage layer includes a silicon nitride film.

15. The manufacturing method of a semiconductor integrated circuit device according to claim 13, further comprising the step of: forming a third insulator between said charge storage layer and said third gate electrode.

16. The manufacturing method of a semiconductor integrated circuit device according to claim 13,
wherein said non-volatile memory cell stores electrons in said charge storage layer and holds the data.

17-30. (cancelled)
